(19) United States
(12) Patent Application Publication
(10) Pub. No.: US 2025/0316549 A1
(43) Pub. Date: Oct. 9, 2025

(54) SEMICONDUCTOR PACKAGE AND METHOD FOR FABRICATION THE SAME

(71) Applicant: Samsung Electronics Co., Ltd., Suwon-si (KR)

(72) Inventor: Duckgyu Kim, Suwon-si (KR)

(21) Appl. No.: 18/937,122

(22) Filed: Nov. 5, 2024

(30) Foreign Application Priority Data
Apr. 9, 2024 (KR) 10-2024-0048054

(51) Int. Cl. H01L 23/31; H01L 21/268; H01L 21/56; H01L 23/00

(52) U.S. Cl. CPC H01L 23/3178; H01L 21/268; H01L 21/56; H01L 24/20; H01L 2224/214

(57) ABSTRACT

A method of fabricating a semiconductor package includes providing a substrate that includes a chip region including a semiconductor device and a surrounding region that at least partially surrounds the chip region, forming a recess part that extends from a first side of the chip region into the surrounding region, forming a coating film that at least partially overlaps the chip region and the surrounding region in a first direction that is perpendicular to an upper surface of the substrate, where the coating film exposes a portion of the recess part, and cutting the portion of the recess part exposed by the coating film.

### CROSS-REFERENCE TO RELATED APPLICATION(S)

This application claims the benefit of Korean Patent Application No. 10-2024-0048054, filed on Apr. 9, 2024, in the Korean Intellectual Property Office, the disclosure of which is incorporated herein by reference.

### TECHNICAL FIELD

Example embodiments relate to a semiconductor package and a method of fabricating the semiconductor package.

### BACKGROUND

When semiconductor is cut for packaging, stress may occur in the area where the semiconductor is cut. This stress may cause cracks to form in the cut area of the semiconductor, reducing the strength of the semiconductor. Accordingly, various studies are being conducted related thereto.

### SUMMARY

An aspect provides a semiconductor package and a method of fabricating the semiconductor package by which the strength of semiconductor devices is improved by preventing cracks in the area where the semiconductor is cut in the semiconductor cutting process.

The technical tasks to be achieved by the present example embodiments are not limited to the technical tasks described above, and other technical tasks may be inferred from the following example embodiments.

According to an aspect, there is provided a semiconductor package including a chip region including a semiconductor device, a substrate that is placed around the chip region and includes a surrounding region that includes one side that is placed at a level different from a level of one side of the chip region, and a coating film that covers the chip region and the surrounding region, wherein the surrounding region has at least a portion that is exposed from the coating film and the coating film is separated apart from one side surface of the surrounding region.

According to another aspect, there is provided a method of fabricating a semiconductor package, the method including providing a substrate that includes a chip region including a semiconductor device and a surrounding region that at least partially surrounds the chip region, forming a recess part that extends from a first side of the chip region into the surrounding region, forming a coating film that at least partially overlaps the chip region and the surrounding region in a first direction that is perpendicular to an upper surface of the substrate, where the coating film exposes a portion of the recess part, and cutting the portion of the recess part exposed by the coating film.

According to another aspect, there is provided a method of fabricating a semiconductor package, the method including providing a substrate that includes a first chip region including a first semiconductor device, a second chip region including a second semiconductor device, and a surrounding region between the first chip region and the second chip region, forming a recess part in the surrounding region, where the recess part extends from a first side of the first chip region and a first side of the second chip region, forming a pre-coating film that is on the first chip region, the second chip region, and the surrounding region, and is in the recess part, forming a first coating film on the first chip region and forming a second coating film on the second chip region by removing a portion of the pre-coating film to expose a central region of the recess part, forming a bump that is electrically connected to the first semiconductor device, and cutting the central region of the recess part.

According to another aspect, there is provided a method of fabricating a semiconductor package, the method including forming a substrate that includes a first chip region including a first semiconductor device, a second chip region including a second semiconductor device, and a surrounding region between the first chip region and the second chip region, forming a recess part in the surrounding region, forming a pre-coating film that is on the first chip region, the second chip region, and the surrounding region, and is in the recess part, and forming a first coating film on the first chip region and forming a second coating film on the second chip region by removing a portion of the pre-coating film to expose a central region of the recess part, and cutting the central region of the recess part, where the first coating film has a first width in a first direction that is parallel to an upper surface of the substrate that is greater than a width of the first chip region in the first direction.

Additional aspects of example embodiments will be set forth in part in the description which follows and, in part, will be apparent from the description, or may be learned by practice of the disclosure.

According to example embodiments, it is possible to enhance the strength of the semiconductor package. This is due to a coating film covering or overlapping an edge part inhibiting movement of residues due to vibration and so on during the cutting process.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a cross-sectional view illustrating a cross-section of a semiconductor package according to an example embodiment;

FIG. 2 is a diagram illustrating a substrate packaged by a method of fabricating a semiconductor package according to an example embodiment;

FIG. 3 is an enlarged view of a portion of FIG. 2;

FIGS. 4, 5, and 6 are diagrams to explain operations for forming a recess part of a semiconductor package according to some example embodiments;

FIGS. 7, 8, 9, 10, and 11 are diagrams for explaining operations of forming a coating film of a semiconductor package according to some example embodiments;

FIGS. 12 and 13 are diagrams for explaining operations of forming bumps of a semiconductor package according to some example embodiments; and

FIGS. 14, 15, and 16 are diagrams for explaining operations of cutting a substrate of a semiconductor package according to some example embodiments.

### DETAILED DESCRIPTION

Prior to the detailed description of the present disclosure, terms or words used in the specification and claims should not be construed as limited to their common or dictionary meanings. Further, the terms or words should be interpreted with meaning and concept consistent with the technical idea of the present disclosure based on the principle that the inventor may appropriately define the concept of terms in order to explain the present disclosure. The example embodiments described in this specification and the configurations shown in the drawings are example embodiments of the present disclosure, and do not necessarily represent the entire technical idea of the present disclosure. Accordingly, at the time of filing the present disclosure, there may be various equivalents and modifications that can replace them.

The same reference numeral or sign shown in each drawing attached to the specification may represent parts or components that perform substantially the same function. For convenience of description and understanding, different embodiments may be described using the same reference numerals or symbols. In other words, even if a component or an element having the same reference numeral is shown in multiple drawings, the multiple drawings may not all represent one example embodiment.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction.

Further, in the following description, expressions such as an upper side, top, a lower side, bottom, a side, front and a back side are expressed based on the direction shown in the drawing. If the direction of the object changes, it may be expressed differently.

Further, in the specification and claims, terms including ordinal numbers such as “first,” “second,” etc. may be used to distinguish between components or elements. These ordinal numbers are used to distinguish identical or similar components from each other, and the meaning of the terms should not be interpreted limitedly due to the use of such ordinal numbers. For example, components or elements combined with these ordinal numbers should not be interpreted as having a limited order of use or arrangement based on the number. If necessary, each ordinal number may be used interchangeably.

Hereinafter, example embodiments of the present disclosure will be described in detail with reference to the attached drawings. However, the spirit of the present disclosure may not be limited to the example embodiments. For example, a person skilled in the art who understands the spirit of the present disclosure may suggest other example embodiments that are included within the scope of the spirit of the present disclosure through addition, change, or deletion of components or elements: however, such example embodiments are intended to be included within the scope of the present disclosure. The shapes and sizes of elements in the drawings may be exaggerated for clearer explanation.

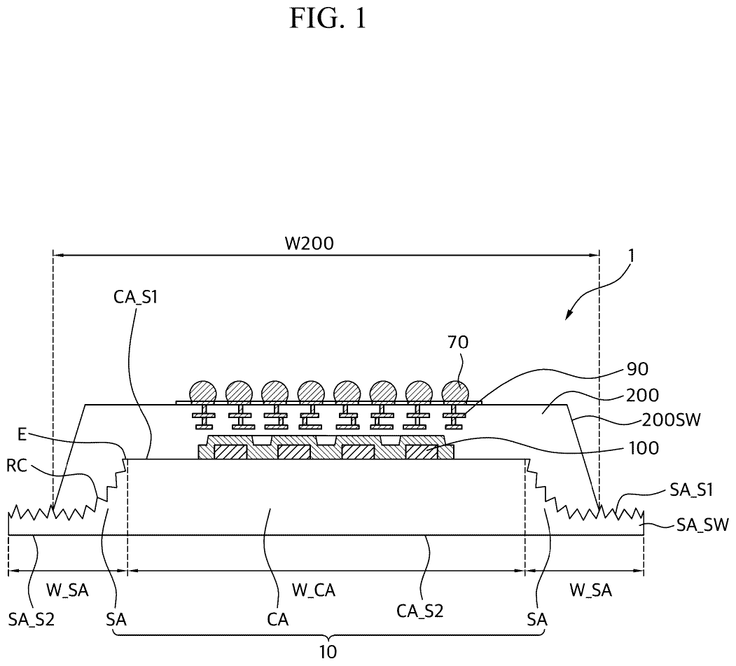

FIG. 1 is a cross-sectional view illustrating a cross-section of a semiconductor package according to an example embodiment.

Referring to FIG. 1, a semiconductor package 1 may include a substrate 10, a coating film 200, wiring structures 90 and bumps 70.

According to some example embodiments, the substrate 10 may include a chip region CA and a surrounding region SA. The chip region CA may include semiconductor devices 100. The chip region CA may be at least partially surrounded by the surrounding region SA.

According to some example embodiments, the surrounding region SA may be placed around the chip region CA. The surrounding region SA may be placed at a level different from a level of the chip region CA relative to an upper surface of the substrate 10 and in a direction that is perpendicular to the upper surface of the substrate 10 (hereinafter “vertical direction”). Specifically, a first side SA_S1 of the surrounding region may be placed at a level different from a level of a first side CA_S1 of the chip region relative to the upper surface of the substrate 10.

According to some example embodiments, the surrounding region SA may include a recess part RC. The recess part RC may be indented or may extend from the first side CA_S1 of the chip region. The recess part RC may have a surface roughness that is greater than surface roughness of the first side CA_S1 of the chip region. For example, the recess part RC may include structures such as bumps or protrusions.

According to some example embodiments, a second side SA_S2 of the surrounding region may be coplanar with a second side CA_S2 of the chip region. The second side SA_S2 of the surrounding region and the second side CA_S2 of the chip region may be placed at the same level relative to the upper surface of the substrate 10. Based on the second side SA_S2 of the surrounding region and the second side CA_S2 of the chip region, a level of the first side SA_S1 of the surrounding region may be placed below a level of the first side CA_S1 of the chip region relative to the upper surface of the substrate 10. In other words, the first side SA_S1 of the surrounding region may be placed closer to the second side SA_S2 of the surrounding region and the second side CA_S2 of the chip region than the first side CA_S1 of the chip region.

According to some example embodiments, the coating film 200 may cover or at least partially overlap the chip region CA and the surrounding region SA. The coating film 200 may cover or at least partially overlap the entire chip region CA. The coating film 200 may overlap the entire chip region CA in the vertical direction.

According to some example embodiments, the coating film 200 may cover or overlap a portion of the surrounding region SA but not another portion of the surrounding region SA. That is, the coating film 200 may expose at least a portion of the surrounding region SA. In other words, the coating film 200 may not overlap at least a portion of the surrounding region SA in the vertical direction. The coating film 200 may be spaced apart from one side surface of the surrounding region SA. Specifically, a side wall 200SW of the coating film may be spaced apart from the side wall SA_SW of the surrounding region in a horizontal direction that is perpendicular to the vertical direction.

According to some example embodiments, the side wall 200SW of the coating film may have a shape that is inclined with respect to a first side of the substrate 10. For example, the side wall 200SW of the coating film may be tilted or inclined at an angle such that it is not perpendicular to the second side SA_S2 of the surrounding region and the second side CA_S2 of the ship region. The tilted shape of the coating film 200 may be formed in the process of removing a portion of the coating film 200 in order for the coating film 200 to expose a portion of the surrounding region SA.

According to some example embodiments, the coating film 200 may cover or at least partially overlap an edge part E. The edge part E may be an interface of the first side CA_S1 of the chip region and the first side SA_S1 of the surrounding region. The coating film 200 is disposed from the chip region CA to a portion of the surrounding region SA, and thus the coating film 200 may cover or at least partially overlap the edge part E.

According to some example embodiments, a value of a width W200 of the coating film in the horizontal direction may be greater than a value of a width W_CA of the chip region in the horizontal direction. The coating film 200 is disposed from the chip region CA to a portion of the surrounding region SA, and thus the value of the width W200 of the coating film in the horizontal direction may be greater than the value of the width W_CA of the chip region in the horizontal direction.

According to some example embodiments, the coating film 200 may include an insulating material. For example, the coating film 200 may be made of at least one material selected from phenol resins, epoxy resins and polyimide. For example, the coating film 200 may include at least one material selected among FR-4, tetrafunctional epoxy, polyphenylene ether, epoxy/polyphenylene oxide, bismaleimide triazine (BT), Thermount, cyanate ester, polyimide and liquid crystal polymer. As another example, the coating film 200 may include a solder resist.

According to some example embodiments, the wiring structures 90 may be disposed within the coating film 200. The wiring structures 90 may electrically connect the bumps 70 and the semiconductor devices 100. For example, the wiring structures 90 may include a plurality of wiring patterns extending parallel to the substrate 10 and a plurality of vias that connect each of the wiring patterns vertically. The wiring structures 90 may include a conductive material. For example, the wiring structures 90 may include gold (Au), silver (Ag), copper (Cu), nickel (Ni) or aluminum (Al).

According to some example embodiments, the bumps 70 may be placed on the wiring structures 90. The bump 70 may include a solder ball or a solder bump. For example, the bump 70 may be spherical or elliptical, but the bump 70 is not limited thereto. The number, spacing, arrangement and shape of the bumps 70 are not limited to what is illustrated, and may be various according to a design. For example, the bump 70 may include tin (Sn), indium (In), bismuth (Bi), antimony (Sb), copper (Cu), silver (Ag), zinc (Zn) and lead (Pb) and/or a combination thereof, but the bump 70 is not limited thereto.

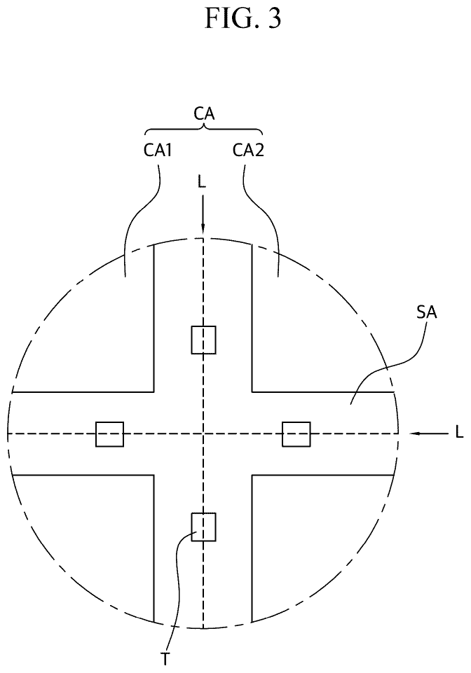

According to some example embodiments, before the process of cutting along a scribe line Lin FIG. 3 for a semiconductor package, the edge part E may be formed for ease of cutting. In the process of forming the edge part E, due to high temperatures, residues formed by melting the substrate 10 may occur. The residues penetrated into the substrate 10 due to vibration during the cutting process may generate a crack in the substrate 10, thereby weakening the strength of the semiconductor package 1.

However, according to example embodiments of the present disclosure, the strength of the semiconductor package 1 may be strengthened. Since the coating film 200 covers or at least partially overlaps the edge part E, during the cutting process, movement of residues due to vibration is limited or inhibited and the crack generation is prevented or inhibited.

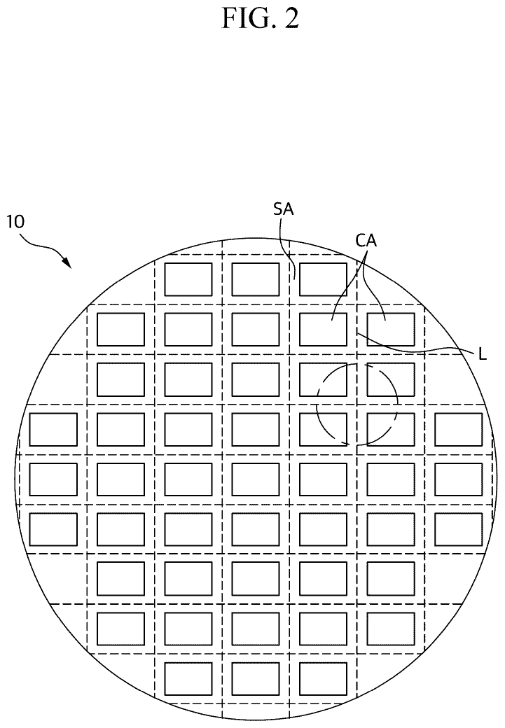

FIG. 2 is a diagram illustrating the substrate 10 packaged by a method S of fabricating a semiconductor package according to an example embodiment. FIG. 3 is an enlarged view of a portion of FIG. 2.

Referring to FIGS. 2 and 3, the substrate 10 may be provided or formed including the chip region CA and the surrounding region SA.

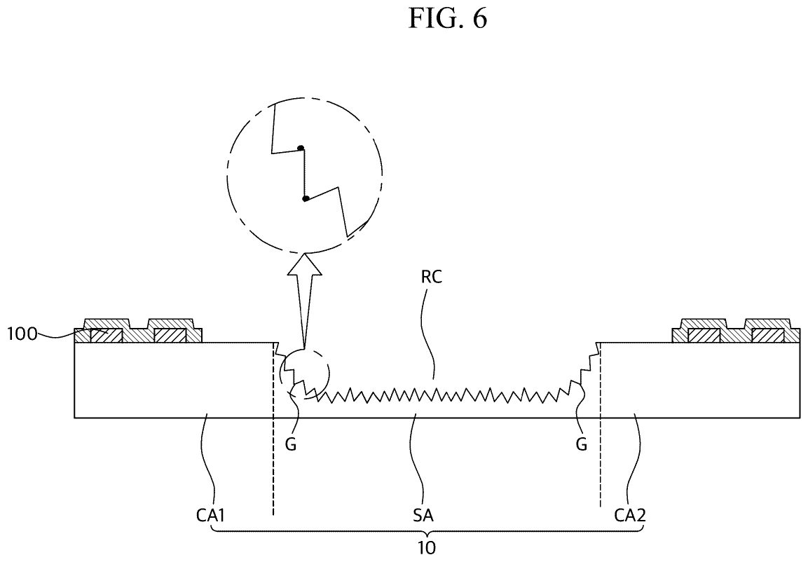

According to some example embodiments, pluralities of the chip region CA may be placed. For example, the chip region CA may include a first chip region CA1 of FIG. 6 and a second chip region CA2 of FIG. 6. The surrounding region SA may be placed between the first chip region CA1 of FIG. 6 and the second chip region CA2 of FIG. 6.

According to some example embodiments, the surrounding region SA may include the scribe line L for cutting in order to separate the plurality of chip regions CA. For example, the scribe line L may be placed in the center or central region of the surrounding region SA in a direction adjacent to the chip region CA. The scribe lines L may extend between the plurality of chip regions CA along the direction in which the chip regions CA are arranged.

According to some example embodiments, the surrounding region SA may include a test element group (TEG) T. The scribe line L may intersect the TEG T. The scribe line L may extend across the TEG T.

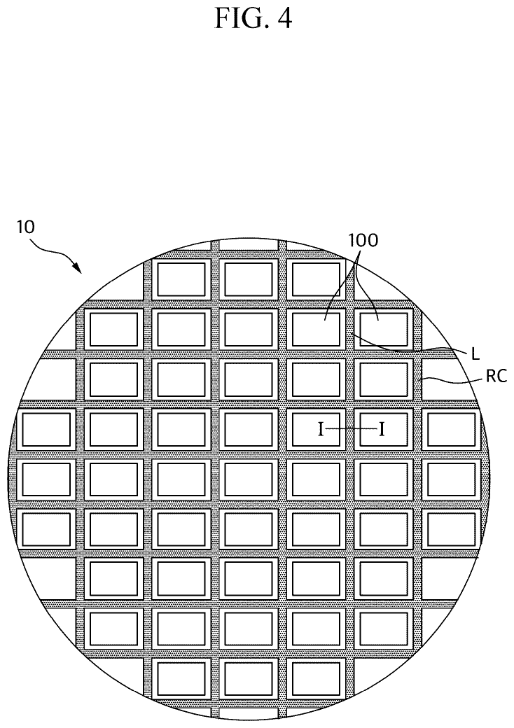

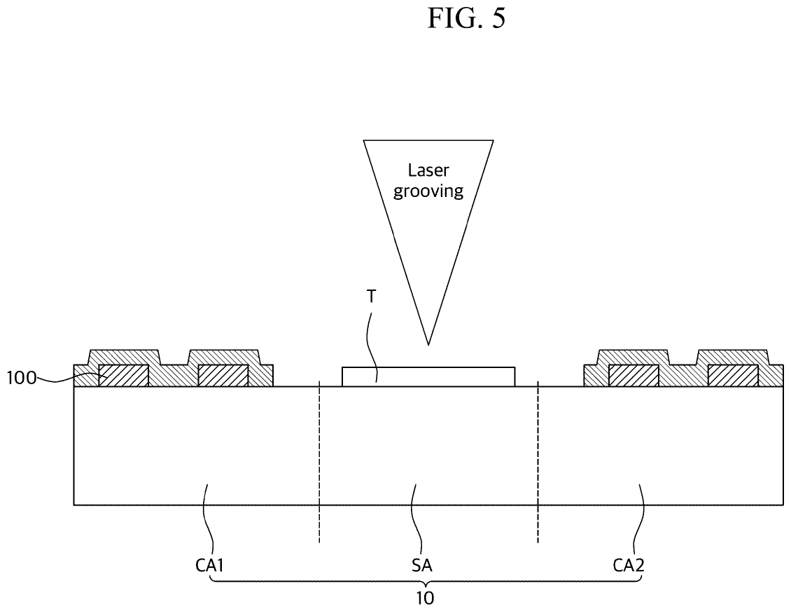

FIGS. 4 to 6 are diagrams to explain operations for forming a recess part RC of a semiconductor package according some example embodiments. Specifically, FIG. 4 is a plan view illustrating the relative relationship between the scribe lines L formed between the plurality of semiconductor devices 100 and the recess part RC. FIG. 5 is a cross-sectional view taken along line I-I of FIG. 4 before the laser grooving process is performed on the substrate 10. FIG. 6 is a diagram illustrating a cross section along line I-I of FIG. 4 after the laser grooving process is performed.

Referring to FIGS. 4 to 6, the recess part RC may be formed in the surrounding region SA. According to some example embodiments, the recess part RC may be placed between the first chip region CA1 and the second chip region CA2. The recess part RC may be indented further than or extend further from a first side of the first chip region CA1 and a first side of the second chip region CA2. The surface of the recess part RC may be more uneven than the first chip region CA1 and the second chip region CA2. For example, a groove G may be formed on the surface of the recess part RC.

According to some example embodiments, the recess part RC may be formed through a laser grooving process and using a laser. Forming the recess part RC may include removing the TEG T of the surrounding region SA by using the laser. In the process of forming the recess part RC, the TEG T of the surrounding region SA may be removed. The process may make the process of cutting the recess part RC easier.

When the TEG T made of metal is provided, if the surrounding region SA is cut immediately without forming the recess part RC, debris formed when the TEG T melts may disperse on the semiconductor devices 100, or cutting itself may be difficult. In the process of forming the recess part RC using a laser, residues such as debris and grooving burrs may be generated around the recess part RC. Debris may be formed when silicon melts, and grooving burrs may refer to a rough surface formed near the recess part RC. Such residues may penetrate into the substrate 10 due to vibration and so on or may cause cracks in the substrate 10 in the cutting process, thereby weakening the strength of the semiconductor package 1.

According to some example embodiments, the recess part RC may overlap the scribe line L in the vertical direction. This arrangement facilitates the cutting process along the scribe line L to separate the first chip region CA1 and the second chip region CA2. However, the recess part RC may not be formed exactly at the scribe line L, but additional trenches may be created around the scribe line L by the laser.

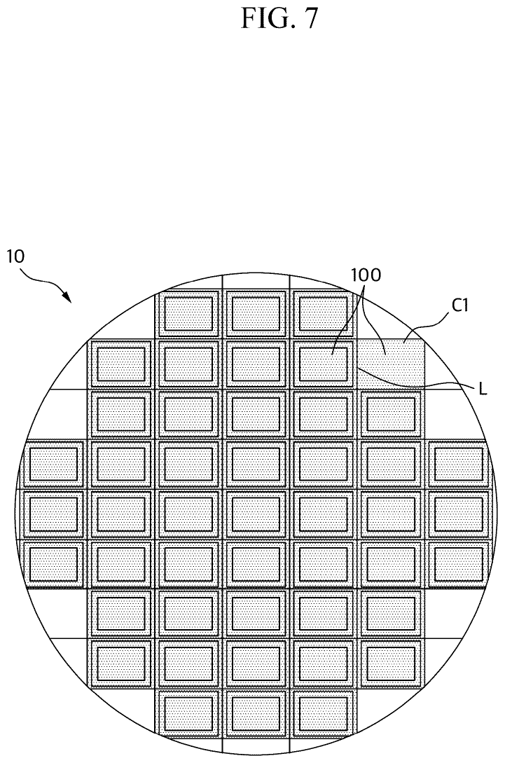

FIGS. 7 to 11 are diagrams for explaining operations of forming the coating film 200 of a semiconductor package according to some example embodiments.

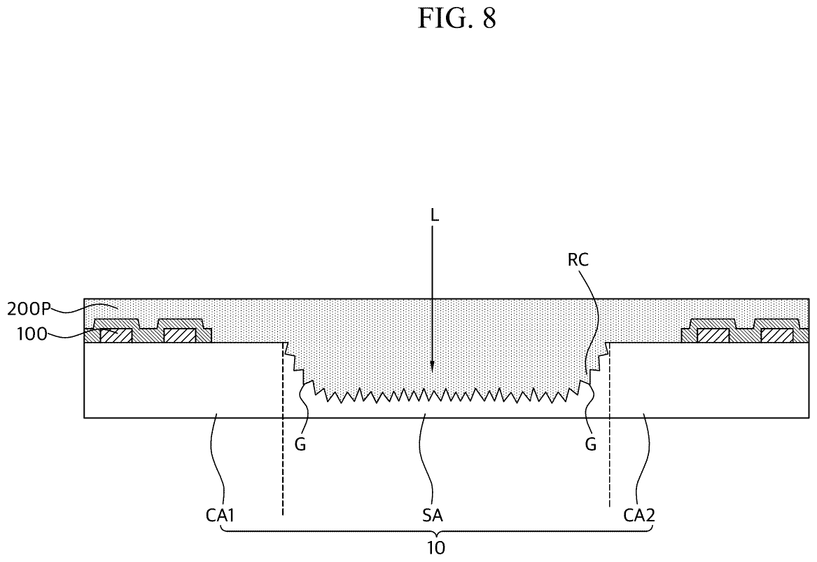

FIG. 7 is a plan view illustrating a state in which a pre-coating film is formed on the plurality of semiconductor devices 100 arranged on the substrate 10. FIG. 8 is a cross-sectional view illustrating a state in which a pre-coating film is formed on the plurality of semiconductor devices 100.

Referring to FIGS. 7 and 8, a pre-coating film 200P may be formed covering or overlapping the chip region CA1, the chip region CA2 and the surrounding region SA.

According to some example embodiments, the pre-coating film 200P may be formed throughout the first chip region CA1, the second chip region CA2 and the surrounding region SA. The pre-coating film 200P may at least partially fill the recess part RC between the first chip region CA1 and the second chip region CA2. The pre-coating film 200P may overlap the entire recess part RC in the vertical direction.

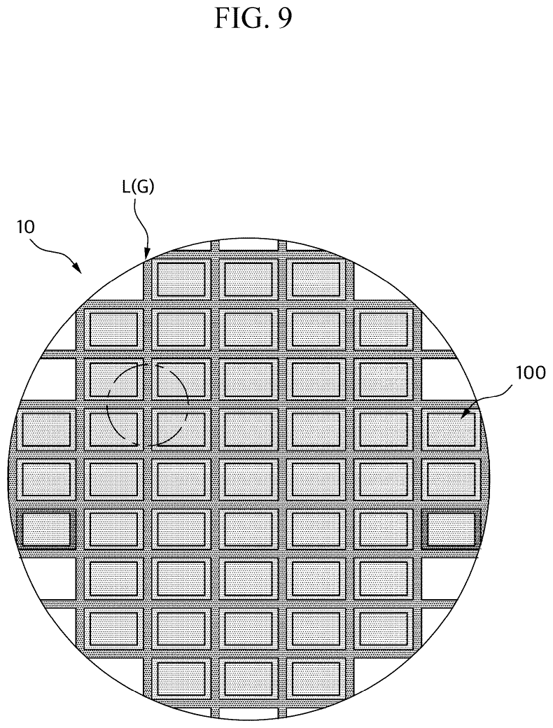

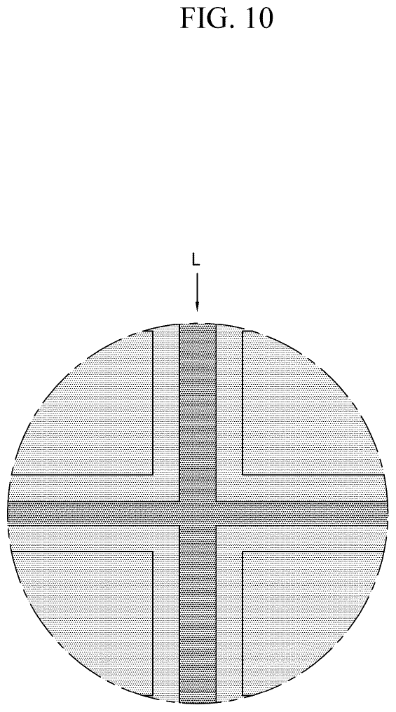

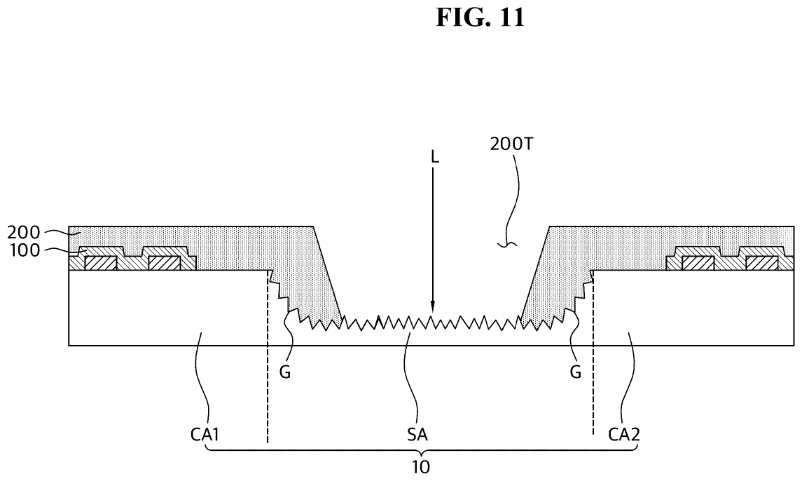

FIG. 9 is a plan view illustrating a state in which the pre-coating film 200P between a plurality of semiconductor devices is removed. FIG. 10 is an enlarged view of a portion of FIG. 9. FIG. 11 is a cross-sectional view illustrating a state in which the pre-coating film 200P between a plurality of semiconductor devices is removed.

Referring to FIGS. 9 to 11, the coating film 200 may be formed exposing at least a portion of the recess part RC.

For example, a coating film trench 200T may be formed in the pre-coating film 200P in FIG. 8 overlapping the recess part RC in the vertical direction. That is, a portion of the pre-coating film 200P in FIG. 8 overlapping the recess part RC in the vertical direction may be removed to form the coating film trench 200T. For example, part of the pre-coating film 200P in FIG. 8 applied to the scribe line L is removed, and thus the coating film trench 200T may be formed. The coating film trench 200T may expose at least a portion of the recess part RC from the coating film 200. The coating film 200 exposing at least a portion of the recess part RC may also expose the scribe line L. The scribe line L may be exposed from the coating film 200 through the coating film trench 200T.

According to some example embodiments, the coating film 200 may include a first coating film 201 and a second coating film 202. The first coating film 201 may cover or at least partially overlap the first chip region CA1. The second coating film 202 may cover or at least partially overlap the second chip region CA2. The first coating film 201 and the second coating film 202 may be spaced apart in the horizontal direction with the coating film trench 200T therebetween.

According to some example embodiments, the coating film trench 200T may separate the first coating film 201 and the second coating film 202. The coating film trench 200T may penetrate or extend into the coating film 200. The side surface of the coating film trench 200T may have a shape inclined with respect to a first side of the substrate 10. In other words, the side surface of the first coating film 201 and the side surface of the second coating film 202 may have a shape that is inclined with respect to a first side of the substrate 10. It is illustrated that the width of the coating film trench 200T in the horizontal direction decreases as it approaches the substrate 10 in the vertical direction, but the present disclosure is not limited thereto.

According to some example embodiments, the coating film 200 may cover or at least partially overlap a portion of the surrounding region SA. The coating film 200 may overlap a portion of the surrounding region SA in the vertical direction. For example, the coating film 200 may cover or at least partially overlap the surrounding region SA adjacent to the first chip region CA1 and the surrounding region SA adjacent to the second chip region CA2. The coating film 200 covering or overlapping the portion of the surrounding region SA may cover or overlap residues formed in the laser grooving process.

According to some example embodiments, the pre-coating film 200P in FIG. 8 may be a photoresist material. Therefore, the pre-coating film 200P in FIG. 8 may be applied to the entire surrounding region SA, including the first chip region CA1, the second chip region CA2 and the scribe line L, and through the exposure and development/formation process, at least a portion of the pre-coating film 200P in FIG. 8 applied to the scribe line L may be removed. The pre-coating film 200P in FIG. 8 may be a positive photoresist material or negative photoresist material, and both a method of removing the coating applied to the scribe line L by providing or irradiating light on the scribe line L and a method of removing the coating applied to the scribe line L by providing or irradiating light in areas excluding the scribe line L may be applied.

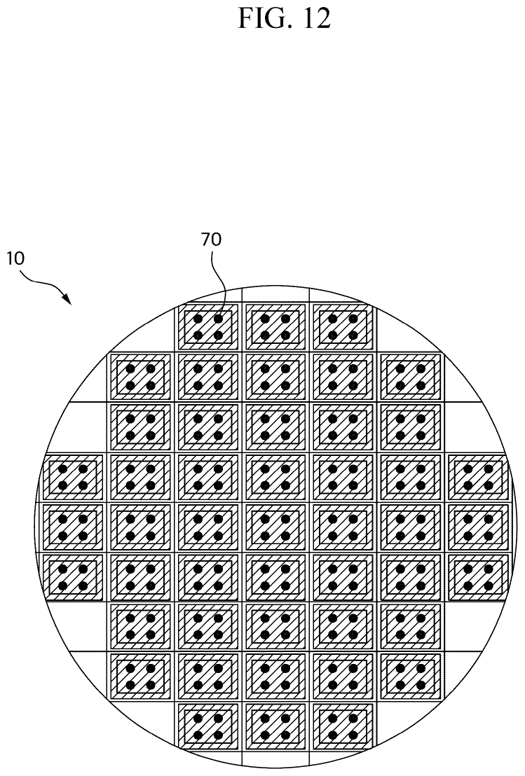

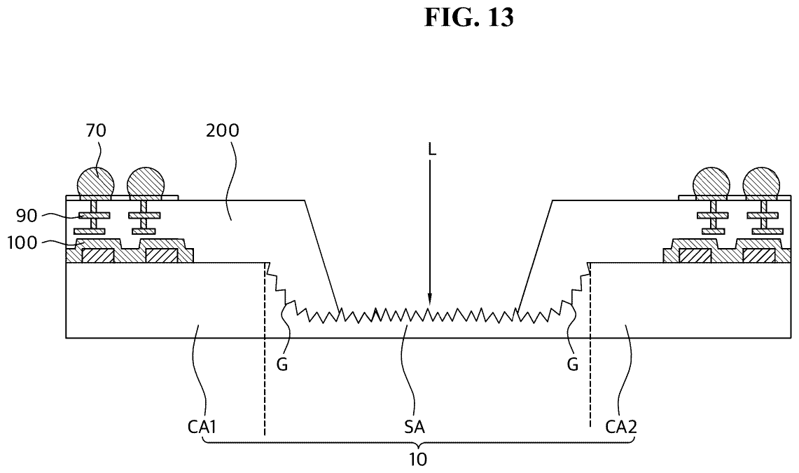

FIGS. 12 and 13 are diagrams for explaining operations of forming bumps in a semiconductor package according to some example embodiments. FIG. 12 is a plan view illustrating a state in which the bumps 70 are formed in a plurality of semiconductor devices. FIG. 13 is a cross-sectional view illustrating a state in which the bumps 70 are formed in a plurality of semiconductor devices.

Referring to FIGS. 12 and 13, the wiring structures 90 may be formed within the coating film 200. The bumps 70 may be formed on the coating film 200. The bumps 70 may be formed on the wiring structures 90.

According to some example embodiments, the bumps 70 may be solder balls. For example, the bumps 70 may include tin (Sn), indium (In), bismuth (Bi), antimony (Sb), copper (Cu), aluminum (Al), silver (Ag), zinc (Zn) and lead (Pb) and/or alloys thereof.

Forming the wiring structures 90 and/or the bumps 70 may be performed before cutting the substrate 10 of the semiconductor package 1, which will be described later. In this case, forming the wiring structures 90 and/or the bumps 70 may be performed together with forming the coating film 200 of the semiconductor package described above. In other words, the insulating film utilized in forming the wiring structures 90 and/or the bumps 70 may be the coating film 200.

However, example embodiments are not limited thereto. Forming the wiring structures 90 and/or the bumps 70 may be performed after cutting the substrate 10 of the semiconductor package 1, which will be described later.

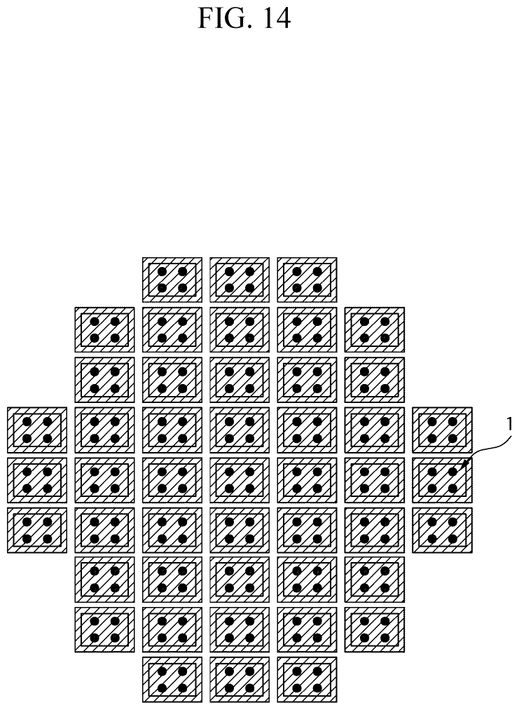

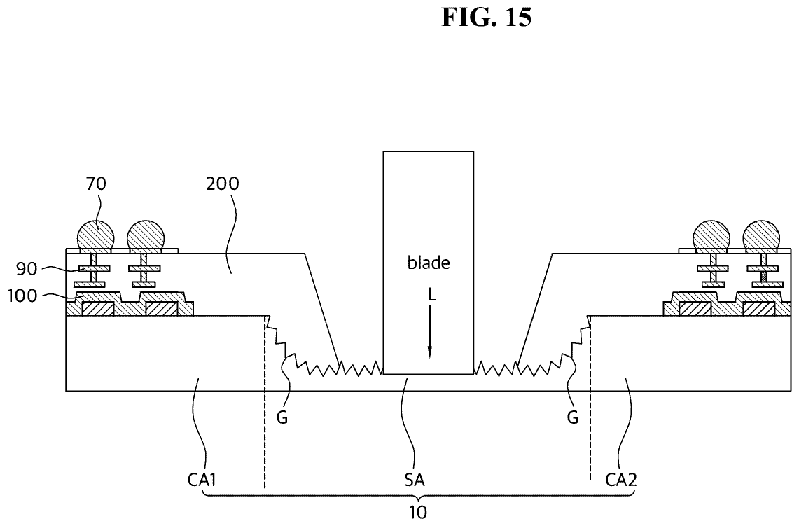

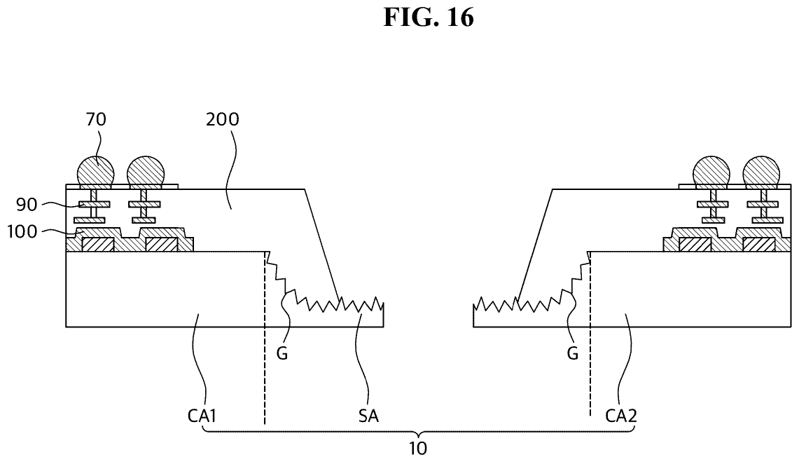

FIGS. 14 to 16 are diagrams for explaining cutting the substrate of a semiconductor package according to some example embodiments. FIG. 14 is a plan view illustrating a state in which a substrate of a semiconductor package is cut. FIG. 15 is a cross-sectional view illustrating the process of cutting a semiconductor package along the scribe line L. FIG. 16 is a cross-sectional view illustrating the semiconductor package after being cut.

Referring to FIGS. 14 to 16, the surrounding region SA may be cut. A blade may cut the surrounding region SA that is not covered with the coating film 200. Specifically, the blade may cut the recess part RC along the scribe line L. The blade may cut the recess part RC while being spaced apart from the coating film 200. By the surrounding region SA being cut, the chip region CA1 and the chip region CA2 may be separated, and the individual semiconductor packages 1 may be fabricated.

The example embodiments are described above with reference to the attached drawings, but the present disclosure is not limited to the example embodiments. A semiconductor package may be fabricated in variety of different example embodiments. A person skilled in the art to which the present disclosure pertains will understand that the present disclosure can be implemented in other specific forms without changing its technical ideas or essential features. Therefore, it should be understood that the example embodiments described above are exemplary in all respects, and are not limiting the present disclosure.

What is claimed is:

1. A semiconductor package comprising:
a chip region that comprises a semiconductor device;
a substrate that at least partially surrounds the chip region and comprises a surrounding region having a first side at a first level relative to an upper surface of the substrate, wherein the first level is different from a second level of a first side of the chip region relative to the upper surface of the substrate; and
a coating film that overlaps the chip region and the surrounding region in a first direction that is perpendicular to the upper surface of the substrate,
wherein the coating film exposes at least a portion of the surrounding region, and
wherein the coating film is spaced apart from a side surface of the surrounding region in a second direction that is parallel to the upper surface of the substrate.

2. The semiconductor package of claim 1, wherein a surface roughness of the first side of the surrounding region is greater than a surface roughness of the first side of the chip region.

3. The semiconductor package of claim 1, wherein the coating film overlaps an edge part, wherein the edge part is an interface of the first side of the chip region and the first side of the surrounding region.

4. The semiconductor of claim 1, wherein the coating film comprises a side surface that is sloped relative to the upper substrate.

5. The semiconductor package of claim 1, wherein a width of the coating film in the second direction is greater than a width of the chip region in the second direction.

6. The semiconductor package of claim 1, wherein the coating film comprises an insulating material.

7. The semiconductor package of claim 1, further comprising a conductive bump that is on the coating film.

8. The semiconductor packages of claim 1, wherein the surrounding region comprises a recess that extends from the first side of the chip region.

9. A method of fabricating a semiconductor package, the method comprising:
providing a substrate that comprises a chip region comprising a semiconductor device and a surrounding region that at least partially surrounds the chip region;
forming a recess part that extends from a first side of the chip region into the surrounding region;
forming a coating film that at least partially overlaps the chip region and the surrounding region in a first direction that is perpendicular to an upper surface of the substrate, wherein the coating film exposes a portion of the recess part; and
cutting the portion of the recess part exposed by the coating film.

10. The method of claim 9, wherein forming the coating film further comprises:
forming a pre-coating film that in an entirety of the recess part; and
exposing the portion of the recess part by removing a portion of the pre-coating film.

11. The method of claim 9, wherein the surrounding region comprises a scribe line, and wherein the recess part is cut along the scribe line.

12. The method of claim 11, wherein the scribe line is on the portion of the recess part that is exposed by the coating film.

13. The method of claim 9, wherein forming the recess part further comprises performing, by a laser, a laser grooving process.

14. The method of claim 9, wherein providing the substrate further comprises forming a test element group (TEG) in the surrounding region.

15. The method of claim 14, wherein forming the recess part further comprises removing, by a laser, the TEG.

16. The method of claim 9, further comprising forming a conductive bump that is electrically connected to the semiconductor device.

17. The method of claim 9, wherein the recess part has surface roughness that is greater than a surface roughness of the first side of the chip region.

18. A method of fabricating a semiconductor package, the method comprising:
providing a substrate that comprises a first chip region comprising a first semiconductor device, a second chip region comprising a second semiconductor device, and a surrounding region between the first chip region and the second chip region;
forming a recess part in the surrounding region, wherein the recess part extends from a first side of the first chip region and a first side of the second chip region;
forming a pre-coating film that is on the first chip region, the second chip region, and the surrounding region, and is in the recess part;
forming a first coating film on the first chip region and forming a second coating film on the second chip region by removing a portion of the pre-coating film to expose a central region of the recess part;
forming a bump that is electrically connected to the first semiconductor device; and
cutting the central region of the recess part.

19. The method of claim 18, wherein the first coating film has a width in a first direction that is parallel to an upper surface of the substrate that is greater than a width of the first chip region in the first direction.

20. The method of claim 18, wherein the recess part has a surface roughness that is greater than a surface roughness of the first side of the first chip region and a surface roughness of the first side of the second chip region.
